(19) United States
(12) Patent Application Publication
(10) Pub. No.: US 2026/0188970 A1
(43) Pub. Date: Jul. 2, 2026

(54) HYBRID SILICON III-V OPTICAL DEVICES WITH THICK METALLIZATION OVER GAIN MEDIUM

(71) Applicant: Intel Corporation, Santa Clara, CA (US)

(72) Inventors: Pierre Doussiere, Santa Clara, CA (US); Aditi Mallik, Cupertino, CA (US)

(73) Assignee: Intel Corporation, Santa Clara, CA (US)

(21) Appl. No.: 19/002,567

(22) Filed: Dec. 26, 2024

(51) Int. Cl. H01S 5/024; G02B 6/13; H01S 5/22; H01S 5/343

(52) U.S. Cl. CPC H01S 5/02469; G02B 6/13; H01S 5/22; H01S 5/343

(57) ABSTRACT

In a photonic integrated circuit (PIC) die, active hybrid silicon III-V optical device structures, including a silicon optical waveguide and a III-V semiconductor material stack, are integrated with a body of metallization. The body of metallization may have a large area and sufficient thickness to function as an integrated die-level heat spreader, reducing thermal resistance of a portion of the PIC die local to the active hybrid silicon III-V optical device structure. The body of metallization may have a thickness exceeding 3 μm over a length and width exceeding those of an underlying active hybrid silicon III-V optical device structure. In laser or SOA structures, the body of metallization may enhance extraction of heat from the laser or SOA to a package-level heat sink assembled with the PIC die. In some examples, a thermal interface material within a package is in direct contact with the body of metallization.

### BACKGROUND

Photonic integrated circuits (PICs) are increasingly important in high-performance computing, data center, and cloud computing applications. The use of silicon in photonics (SiPh), enables high-volume, low-cost and highly integrated PICs. The provisioning of on-chip active optical devices, such as lasers, is a critical path in PIC development, particularly for applications relying on dense wavelength division multiplexing (DWDM). Along with lower manufacturing costs, the integration of active optical devices directly on silicon would reduce coupling losses for SiPh applications.

A “hybrid silicon” active optical device heterogeneously integrates III-V material with a silicon substrate comprising an optical waveguide. Active optical devices include an optical gain medium with some examples including lasers and semiconductor optical amplifiers (SOAs). For hybrid optical device architectures, the gain (active) material may be in the form of quantum dot structures or quantum well layers, for example.

Hybrid silicon active optical device architectures that can improve laser power and/or improve SOA power are commercially advantageous, but can suffer from poor heat dissipation when packaged in an optical transceiver. One problem is that a hybrid optical device may be on a silicon substrate that includes a buried oxide layer, which reduces heat extraction from a backside surface through the silicon substrate. In an effort to improve heat extraction from an active optical device, an intermediary, for example a chiplet of silicon, may be inserted between a frontside surface the PIC and a package heat sink or other package-level thermal solution. This intermediary may be attached to the PIC through copper bump interconnects, for example. However, such PIC package architectures can incur significant assembly cost and may still display relatively high thermal resistance (e.g., 50-60° C./W).

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram of methods for fabricating a hybrid silicon optical device, in accordance with some embodiments;

FIG. 2 is a cross-sectional view a silicon PIC substrate, in accordance with some embodiments;

FIG. 3A is a plan view of an optical waveguide within a silicon PIC substrate, in accordance with some embodiments;

FIG. 3B is a cross-sectional profile view of an optical waveguide with a silicon PIC substrate, in accordance with some embodiments;

FIG. 4-5 are cross-sectional profile views of a PIC die structure including a III-V-Si hybrid optical device evolving as methods illustrated in FIG. 1 are practiced, in accordance with some embodiments;

FIG. 6A is a plan view of a PIC die structure with a III-V-Si hybrid optical device evolving as methods illustrated in FIG. 1 are practiced, in accordance with some embodiments;

FIGS. 6B, 7 and 8A are a cross-sectional profile views of a PIC die structure with a III-V-Si hybrid optical device evolving as methods illustrated in FIG. 1 are practiced, in accordance with some embodiments;

FIG. 8B is a cross-sectional profile view of the PIC die structure illustrated in FIG. 8A, in accordance with some embodiments;

FIG. 8C is a plan view of the PIC die structure illustrated in FIG. 8A, in accordance with some embodiments;

FIG. 9 illustrates a cross-sectional profile view of a package assembly including a PIC die structure with a hybrid silicon optical device, in accordance with some further embodiments;

FIG. 10 illustrates a mobile computing platform and a data server machine comprising a packaged PIC including a plurality of hybrid silicon optical devices, in accordance with some embodiments; and

FIG. 11 is a functional block diagram of an electronic computing device, that may implement one or more of the components of the mobile platform or data server machine illustrated in FIG. 10, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

The inventors have found that for a photonic integrated circuit (PIC) die including hybrid silicon III-V active optical devices, heat dissipatecan be can be significantly improved at relatively low cost by integrating a thick body of thermally conductive material, such as a body of metallization, into the PIC die. At sufficient thickness, the thermally conductive material can spread heat generated by an active device, such as a laser or semiconductor optical amplifier, over a large area of the PIC die, thereby reducing thermal resistance of the top/front side of the PIC die. Greater heat dissipation through the top/front side of the PIC die can be particularly advantageous where heat dissipation through the bottom/back side of the PIC die is limited, for example by one or more thermally insulative material layers, such as a buried substrate layer.

According to some exemplary embodiments herein, active hybrid silicon optical device structures including a silicon optical waveguide and a III-V semiconductor material stack are located below a body of metallization that may be fabricated in the PIC die with any technique(s) suitable for depositing thermally conductive thin films of multiple micrometers in thickness. With the integration of a thick body of metallization, a laser may generate higher power light emission or an SOA may achieve higher saturation power without suffering thermal runaway and/or other failure modes negatively impacting optical device reliability. Additionally, a thick body of metallization may mechanically protect any underlying active optical device from damage during PIC die packaging. For example, the thick body of metallization may shelter a laser or SOA from mechanical forces associated with the application of a thermal interface material (TIM) to a frontside surface of a PIC die structure. In further embodiments, the TIM may be applied directly to a surface of the body of metallization to maximize heat extraction from the PIC die.

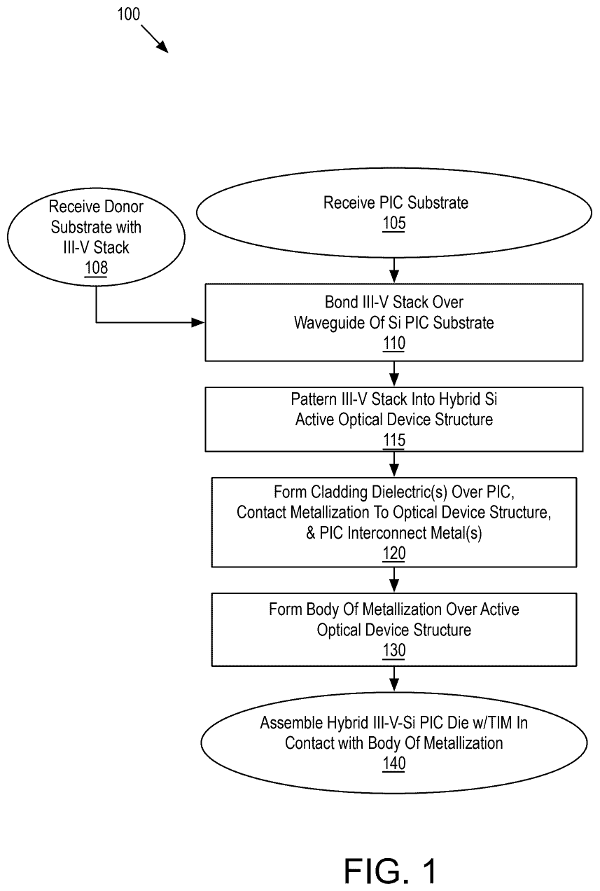

FIG. 1 is a flow diagram of methods 100 for integrating a hybrid silicon active optical device, such as an SOA or laser, with a die-level heat spreader, in accordance with some embodiments. Methods 100 may be practiced, for example, to integrate a hybrid silicon laser (HSL) with a die-level heat spreader having one or more of the structural attributes described herein. Methods 100 may also be practiced to integrate a die-level heat spreader with other hybrid silicon devices, such as an SOA. In some exemplary embodiments, methods 100 further assemble one or more photonic integrated circuit (PIC) die structure that includes a thick body of metallization with a package-level TIM and a package-level thermal solution. Although examples are described in the context of laser and SOA implementations, the exemplary architectures may be further applied to alternative hybrid silicon optical devices, such as a modulator, or may be applied instead to non-hybridized active optical devices that face similar thermal challenges.

Methods 100 begin at input 105 where a PIC die workpiece is received. The workpiece may comprise a wafer or panel, for example of a semiconductor material suitable for the fabrication of a PIC. In some embodiments, the workpiece has a diameter of at least 300 mm, but may also be of any other dimension(s). In some examples, the workpiece received at input 105 comprises a semiconductor on insulator (SOI) substrate that further comprises a semiconductor substrate material and a buried insulator layer, for example between a top (front) side substrate semiconductor material layer and another substrate semiconductor material layer on a bottom (back) side of the insulator layer. In exemplary hybrid-silicon embodiments, the SOI substrate includes silicon and a buried layer of silicon dioxide.

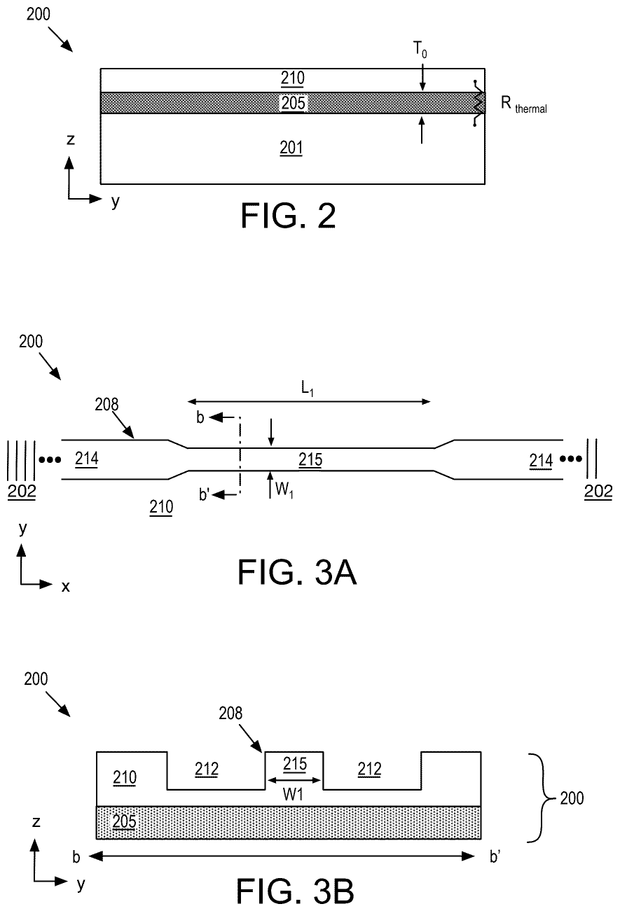

FIG. 2 illustrates a cross-sectional profile through an exemplary workpiece where a PIC die structure 200 is to be fabricated. PIC die structure 200 comprises a portion of a substrate material layer 201. In exemplary embodiments, substrate material layer 201 comprises substantially monocrystalline silicon. Substrate material layer 201 is a base layer of an SOI substrate material stack further comprising a buried insulator material layer 205. In exemplary embodiments, where substrate material layer 201 is substantially pure silicon, insulator material layer 205 is advantageously predominantly silicon and oxygen and may be essentially pure silicon dioxide (e.g., SiO₂). One or more additional substrate material layers are over insulator material layer 205. In the example illustrated in FIG. 2, buried insulator material layer 205 is between substrate material layer 201 and a device material layer 210. In some embodiments where substrate material layer 201 is substantially monocrystalline silicon, device material layer 210 is also substantially monocrystalline silicon. As further illustrated in FIG. 2, buried insulator material layer 205 may have a lower material thermal conductivity (W/mK) than both device material layer 210 and substrate material layer 201. Accordingly, as a function of buried layer thickness T₀, buried insulator layer 205 may pose high thermal resistance Rₜₕₑᵣₘₐₗ that can limit heat dissipation through substrate material layer 201.

The PIC workpiece received at input 105 (FIG. 1) may include at least one optical waveguide that has been fabricated upstream of methods 100 according to any technique(s) known in the art. The substrate may further comprise one or more other passive optical devices, such as (de) multiplexers, grating couplers, etc. The substrate may also comprise active components such as modulators and/or photodetectors. Such optical devices may have been fabricated into the substrate upstream of methods 100 according to any technique(s) known in the art. Such optical devices may also be fabricated downstream of methods 100.

FIG. 3A is a plan view of PIC die structure 200, in accordance with some laser embodiments. FIG. 3B is a cross-sectional profile view of PIC die structure 200 through the b-b′ plane demarked by the dot-dashed line in FIG. 3A, in accordance with further embodiments. As shown, PIC die structure 200 includes a substantially planar optical waveguide 208 patterned within device material layer 210 or within a thin film on device material layer 210. In exemplary embodiments where device material layer 210 comprises substantially monocrystalline silicon, waveguide 208 is also substantially monocrystalline silicon. In other embodiments, waveguide 208 is predominantly silicon and nitrogen (e.g., Si₃N₄).

Optical waveguide 208 may have any suitable architecture, such as, but not limited to, a substantially planar ridge waveguide of the type having the profile illustrated in FIG. 3B. Optical waveguide 208 may have a substantially constant transverse lateral width W₁ over a longitudinal length L₁ of an active waveguide region 215. Length L₁ may vary with implementation, for example from 100 μm to 2 mm, or more. At opposite ends of active waveguide region 215, waveguide 208 tapers out to passive waveguide regions 214 having a larger transverse width. Although the active waveguide width W₁ may vary, in some exemplary silicon waveguide embodiments width W₁ is in the range of 150 nm to 1 μm. A similar range is also applicable to the z-height (z-axis in FIG. 3B) of at least active waveguide region 215. In the example illustrated, air 212 is over a surface of PIC die structure 200, and adjacent to sidewalls of waveguide 208.

Although implementations may vary, for laser device embodiments at least a portion of optical waveguide 208 may comprise a mirror for establishing a resonant optical cavity within active waveguide region 215, for example according to any suitable Fabry-Perot (FP) laser architecture. In the illustrated embodiment, grating structures 202 are defined within passive waveguide regions 214, for example according to any suitable Distributed Bragg Reflector (DBR) laser architecture. In alternative architectures (e.g., a Distributed Feedback (DFB) laser architecture), one or more grating mirror structures 202 may be located within active waveguide region 215. Mirror structures 202 may be absent from an alternative active optical device structure, such as an SOA.

Returning to FIG. 1, methods 100 continue with receipt of donor substrate at input 108. The donor substrate may include any III-V material stack known to be suitable for an active hybrid silicon III-V device. In some examples, the donor substrate received includes monocrystalline binary GaAs. In some other examples, the donor substrate received includes monocrystalline binary InP. In some other examples, the donor substrate received includes monocrystalline sapphire. The donor substrate may be a bulk monocrystalline material or include some other form of mechanical support.

In exemplary laser and SOA embodiments, the donor substrate received at input 108 includes a III-V P-i-N material stack, which may have been formed upstream of methods 100 according to any epitaxial semiconductor crystal growth process, such as molecular beam epitaxy (MBE) or metal organic chemical vapor deposition (MOCVD). The III-V P-i-N material stack is advantageously substantially monocrystalline and may have any number of material layers. In exemplary embodiments, the P-i-N material stack is an optically active material stack comprising an optical gain material. The gain material may be in the form of multiple quantum well (MQW) material layers or quantum dot (QD) material structures. The gain material(s) may have any chemical composition(s) and any micro/nano structure known to be suitable as MQW or QD optical gain material within one or more optical bands of the electromagnetic energy spectrum.

At block 110, a III-V material stack is transferred from the donor substrate received at input 108 to the PIC substrate received at input 105. Any substrate (wafer)-level film bonding process may be practiced at block 110 to form a hybrid material heterostructure. The term “hybrid” is in reference to resulting structure including non-silicon (e.g., III-V) material layers bonded to underlying silicon (or a silicon-based thin film material layer thereon). Once bonded, the donor substrate may be removed to complete transfer of the P-i-N material stack and the optical mode spacer.

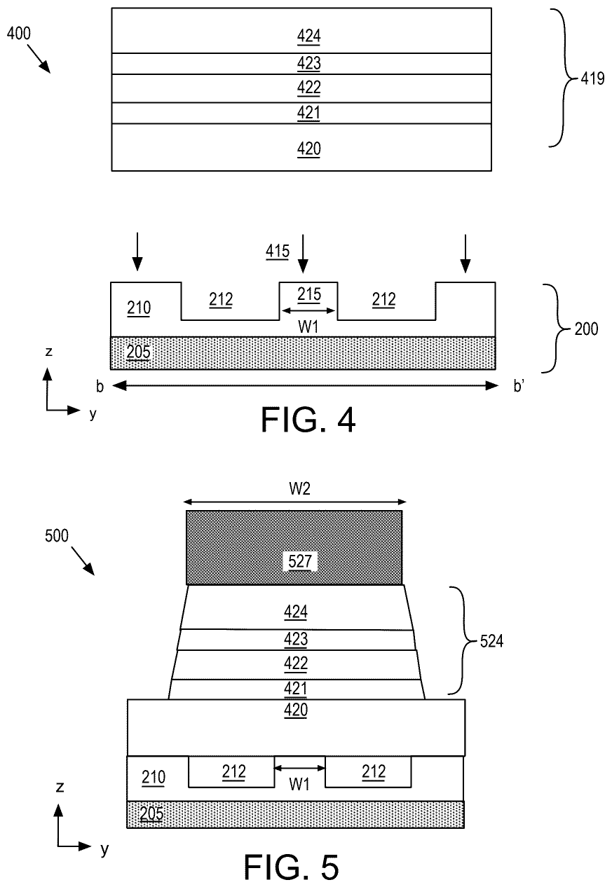

In exemplary embodiments, the III-V material stack is bonded to the PIC substrate such that P-i-N material is directly over the optical waveguide. FIG. 4 illustrates a cross-sectional profile view of a III-V P-i-N material stack 419 being transferred to PIC die structure 200 to form a hybrid silicon III-N device structure 400. In accordance with some embodiments, material layers of P-i-N material stack 419 all comprise a Group III-V crystalline alloy material (i.e., a III-V material stack). Material stack 419 includes a at least one optical gain material layer 422, in accordance with some embodiments. Gain material layer 422 is between an n-type material 420 and a p-type material 424. Material stack 419 is advantageously an epitaxial heterostructure that may have any number of gain material layers between n-type material 420 and p-type material 424. Each optical gain material layer 422 may have any thickness, with 10-50 nm being an exemplary thickness range.

In some examples, optical gain material layer 422 comprises multiple quantum well layers of different III-V alloy compositions and different optical band offsets and/or lattice mismatch. In other examples optical gain material layer 422 comprises quantum dots of a first III-V composition, and a shell material another III-V alloy having a distinct chemical composition with a suitable optical band offset and/or lattice mismatch with that of quantum dots. The chemical composition of layers or structures within gain material layer 422 may be varied over a range of binary, ternary or quaternary III-V alloys, layer thicknesses, and/or nanostructure dimensions. In some embodiments optical gain material layer 422 is suitable for optical gain within a particular energy band (e.g., IR band of 1270 nm-1330 nm),

N-type material 420 and p-type material 424 may comprise one or more electrically active impurity dopants, which may vary with the majority constituents of materials 420, 424. For example, in some embodiments where materials 420 and 424 are both ternary or quaternary alloys including Ga and As (e.g., InGaAsP) n-type material 420 may comprise carbon, beryllium, magnesium, zinc, or cadmium while p-type material 424 may comprise silicon, tellurium or carbon. Electrically active impurity dopant concentrations may vary with implementation to achieve any bulk electrical resistivity suitable for the application. Layer thicknesses of material 420, 424 may also vary (e.g., from hundreds of nanometers to a micrometer, or more) to achieve as sufficiently low external electrical resistance associated with the electrical resistivity of the impurity doped material and a metal-semiconductor junction (contact) resistance.

As further illustrated in FIG. 4, P-i-N material stack 419 further includes separate confinement heterostructures (SCH) 421 and 423, located between gain material layer 422 and each of impurity-doped materials 420, 424. SCH 421 and/or SCH 423 may have any architecture known to be suitable for a particular active optical device and each may comprise a heterostructure including high refractive index material layers of varying optical index and/or band gap. In some examples, SCH 421 and 423 each comprises a quaternary III-V alloy, such as InGaAlAs and/or InGaAsP with significantly lower impurity dopant concentration than that of material layers 420, 424, respectively.

As further shown in FIG. 4, a bonding process 415 places n-type material 420 proximal to optical waveguide 208 and p-type material 424 distal from waveguide 208. In the illustrated example, n-type material 420 makes direct contact with waveguide active region 215. However, in other embodiments, n-type material 420 may be spaced apart from waveguide active region 215 by the thickness of an intervening spacer of III-V material (not depicted). In the illustrated example, P-i-N material stack 419 bridges over air 212 and extends over an adjacent (perimeter) portion of substrate material layer 210. However, other waveguide cladding structures are also possible.

Returning to FIG. 1, methods 100 continue at block 115 where at least some layers of the transferred P-i-N material stack are patterned into a hybrid active optical device structure. One or more dry or wet etch processes may be practiced at block 115, for example. In the embodiment further illustrated in FIG. 5 an HSL structure 500 has been defined from hybrid silicon III-N device structure 400 (FIG. 4). As shown in FIG. 5, a III-V mesa comprises a sidewall 524 that has been etched according to a patterned etch mask 527. As shown, p-type material 424, gain material 422, SCH 421 and SCH 423 have all been etched into a mesa structure having a minimum transverse width W₂. In the illustrated example, n-type material layer 420 remains unpatterned following mesa definition. Mesa width W₂ is substantially centered over waveguide width W₁. In the illustrated example, mesa (top) width W₂ is significantly greater than active optical waveguide transverse width W₁, for example because larger mesa width W₂ may advantageously reduce the thermal resistance of HSL structure 500. Although mesa width W₂ may vary with implementation, in some embodiments mesa width W₂ is 10 μm, or more.

Returning to FIG. 1, methods 100 continue at block 120 where optical cladding is formed over various optical device surfaces of a PIC die. The optical cladding may be a dielectric material, for example, having a suitable index contrast with HSL structures and/or silicon waveguides. Any suitable techniques may be practiced to pattern the cladding and form device contact metallization to complete optical device structures of a PIC die. For an exemplary hybrid silicon device comprising a III-V material mesa, a first contact (e.g., p-contact) metallization feature may be formed over a top surface of p-type material in a III-V mesa while a second contact (e.g., n-contact) metallization feature may be formed on n-type material adjacent to the III-V material mesa.

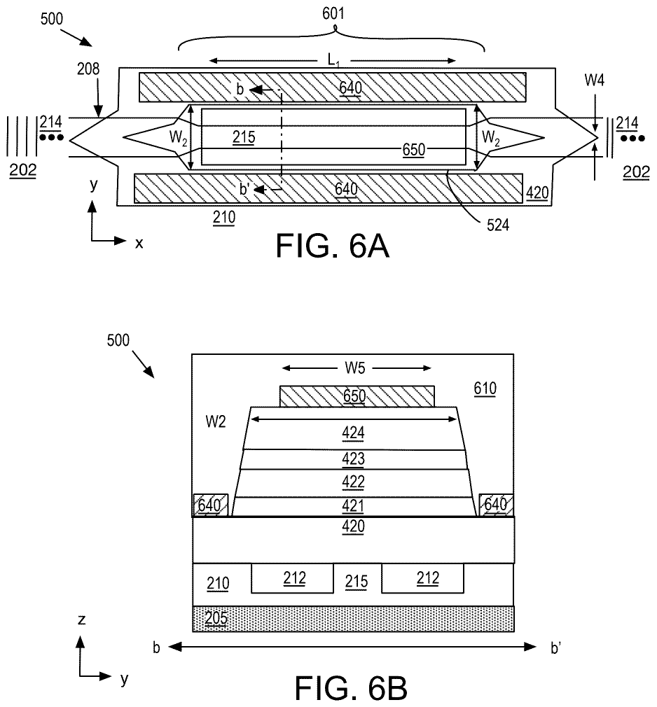

FIG. 6A illustrates a plan view of a hybrid silicon optical device, in accordance with some embodiments. FIG. 6B illustrates a cross-sectional profile view of the hybrid silicon optical device along the b-b′ dot-dash line shown in FIG. 6A, in accordance with some further embodiments. As shown, HSL structure 500 comprises a mesa 601 of substantially constant width over longitudinal length L₁. At opposite ends of length L₁, the mesa width tapers from lateral width W₂ to a first transverse tip width. N-type material 420 similarly tapers from a greater width accommodating contact metallization 640 to a second transverse tip width W₄. The illustrated III-V material tapers overlap complementary tapers in underlying silicon optical waveguide 208 and approximate an adiabatic taper. Over length L₁, optical waveguide 208 is evanescently optically coupled to mesa 601, whereby optical power within the III-V material mesa is transferred into optical waveguide 208.

As shown in FIGS. 6A and 6B, a contact metallization feature 640 is in direct contact with n-type material 420 adjacent to mesa sidewall 524. Contact metallization feature 640 may have any chemical composition known to be suitable for an ohmic or tunneling electrical contact to n-type material 420. Another contact metallization feature 650 is in direct contact with p-type material 424 (FIG. 6B). Contact metallization feature 650 may have any chemical composition known to be suitable for an ohmic or tunneling electrical contact to p-type material 424. As shown, contact metallization feature 650 has a lateral contact width W₅ that is significantly greater than silicon waveguide width W₁ and nearly equal to mesa width W₂. For example, contact width W₅ may be 80%, or more, of mesa width W₂. The larger width W₅ may improve top side heat extraction over the larger mesa width W₂, particularly where a block over metallization is fabricated over mesa 601, as further described herein.

As further depicted in FIG. 6B, one or more dielectric materials 610 may be formed over the active optical device structure and/or contact metallization 640, 650, for example as part of a back-end of line (BEOL) interlevel dielectric (ILD) fabrication module. One or more levels of interconnect metallization features, such as vias and/or lines may be embedded within dielectric materials 610, for example to integrate electrical circuitry within a PIC die.

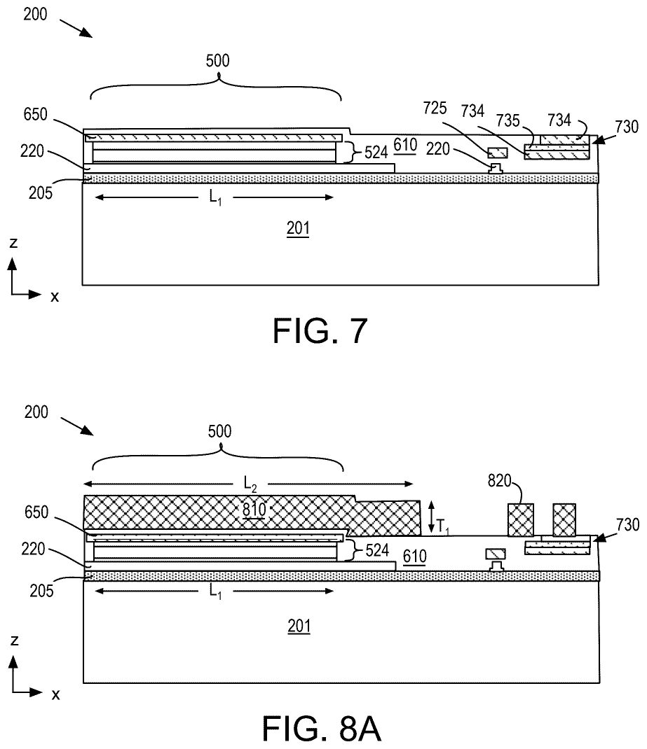

In the example further illustrated in FIG. 7, PIC die structure 200 further includes other (e.g., passive) lengths of optical waveguide 220 embedded within dielectric materials 610. PIC die structure 200 may also include other features, such as a resistive heater element 725, or metal-insulator-metal capacitor 730, which may be integrated within a PIC adjacent to HSL structure 500, for example within one or more levels of metallization that couple together electrical and opto-electrical devices. Heater element 725 may comprise resistive portion of an interconnect line, for example. A metal-insulator-metal (MIM) capacitor 730 is also illustrated as another example of an electrical device that may be fabricated within metallization levels of PIC die structure 200. Metallization features may be formed by practicing any suitable thin film IC die fabrication techniques. Heater element 725 and electrodes 734 of MIM capacitor 730 may comprise a thin film of metal (e.g., W, WNx, Ti, TiNx, etc.) that may be deposited and etched into lines and/or electrodes, etc. One or more thin film dielectric material layers (e.g., MIM capacitor insulator 735, etc.) may be deposited over the interconnect metal features.

Returning to FIG. 1, methods 100 continue at block 130 where, within the PIC die structure, a body of metallization is formed over one or more active optical device structures. The body of metallization is to enhance the lateral spread of heat, increasing an area of a local hot spot in the PIC die structure resulting from heat generated during operation of the underlying active optical device. The body of metallization may further enhance the transport of heat from the underlying active optical device to a package-level thermal solution, external of the PIC die.

Block 130 may include deposition of thermally conductive material over or on a PIC die surface. Although the thermally conductive material may have any composition having a thermal conductivity of at least 100 W/mK. In exemplary embodiments, the thermally conductive film deposited at block 130 is advantageously predominantly a metal. In some advantageous embodiments, the metal is predominantly copper, and may be substantially pure (e.g., 99 wt. %) copper. Although the thermal conductivity of pure copper (e.g., 375-400 W/mK) exceeds that of most other metals, an alternative metal (e.g., gold, silver, aluminum, tungsten, ruthenium, etc.) may be deposited at block 130. Given a large thickness will reduce thermal spreading resistance, metals, such as Cu, Au, and Ag, which can be that be electrolytically plated at high deposition rates are advantageous. However, deposition processes other than plating, such as chemical vapor deposition (CVD) or atomic layer deposition (ALD), may also be practiced at block 130.

The thermally conductive material deposited at block 130 may be deposited to any thickness, for example as a function of the material's thermal conductivity, to spread heat from a first area associated with an underlying active optical device to a second, larger, area that is to be coupled to a package-level thermal solution. Depending on the thickness of thermally conductive material to be formed, block 130 may comprise one or more deposition processes. In some exemplary embodiments (e.g., where copper is deposited), an electrolytic plating process is practiced at block 130. Such plating processes are known to achieve high deposition rates at low cost, enabling the formation of microns thick metallization. A plating process may be preceded by a seed layer deposition process, where a seed metal, such as copper, is deposited, for example with physical vapor deposition (PVD) process. Block 130 may further comprise deposition of an interface material layer, such as an adhesion layer or diffusion barrier layer, having one or more other compositions (e.g., Ta, Ti, Mo, Co, etc.).

For embodiments where the deposition process is non-selective, one or more subtractive film patterning (i.e., etch) processes may be further performed at block 130 to pattern the thermally conductive film into a block (or other polygon) of thermally conductive material positioned over an underlying active optical device. In some embodiments, block 130 comprises a planarization of the conductive material deposited to define a block or other polygon. Such a planarization process may, for example, remove conductive material overburden from a dielectric material in regions beyond a perimeter of the body of metallization. Any planarization (e.g., CMP) process may be practiced to complete patterning.

Alternatively, a body of thermally conductive material may be additively, or semi-additively, formed over an active optical device. In some embodiments, a temporary mask comprising an organic material may be deposited at block 130 and openings through the mask lithographically defined, for example exposing portions of an underlying seed layer. A masked plating process, selective to the seed layer may then be practiced to form a body of metallization within the mask opening. Any masked plating process suitable for forming interconnect bumps or pillars may be practiced at block 130 to form a body of metallization over an active optical device.

Block 130 may comprise multiple material deposition iterations. A damascene or semi-additive plating process may be iterated to form a body of metallization of sufficient thickness to function as an integrated heat spreader. For example, in the fabrication of a PIC die, a damascene metallization process may be repeated for each successive interconnect level that is to include a damascene interconnect structure, and a body of metallization over an active optical device may be cumulatively fabricated as a summation of all the interconnect levels. The body of metallization may therefore comprise multiple layers of metallization (e.g., demarked by intervening seed layers) as opposed to a single homogenous body of metal (e.g., with only one seed layer).

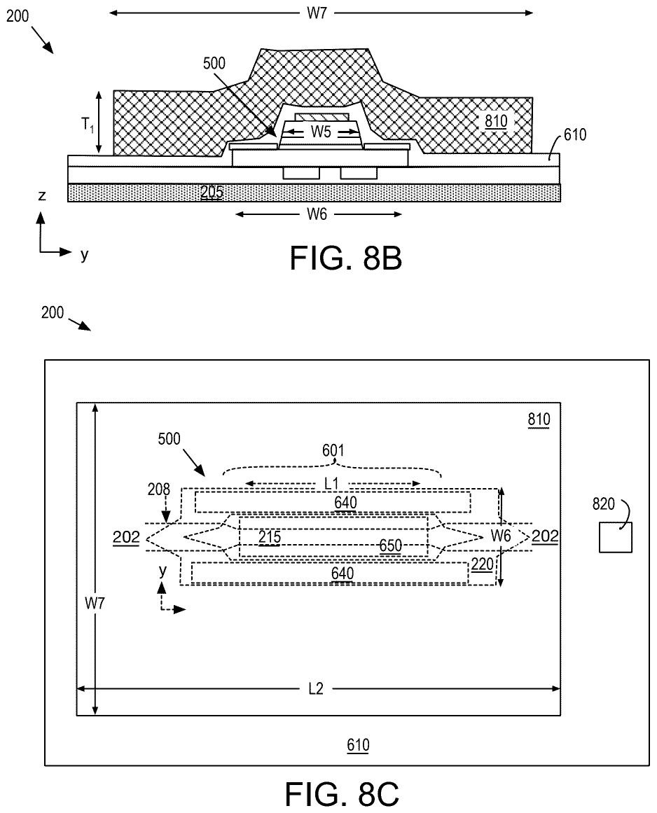

FIG. 8A is a cross-sectional profile view of PIC die structure 200 following formation of a metallization body 810 directly over HSL structure 500. As shown, metallization body 810 has a length L₂ in a first direction (e.g., along x-axis) coincident with length L₁ of HSL structure 500. In exemplary embodiments, length L₂ is at least equal to length L₁, and advantageously greater than length L₁, expanding the length of a path of high thermal conductivity to encompass, or fully cover, HSL structure 500. Metallization body 810 has a thickness T₁ of at least 3 μm. This thickness reduces thermal spreading resistance and also provides mechanical protection to HSL structure 500. In exemplary embodiments where metallization body 810 is predominantly copper and thickness T₁ advantageously exceeds 5 μm, the inventors estimate that for a stress applied to a top of surface of PIC die structure 200, for example during application of a thermal interface material, less than 80% is transmitted to HSL structure 500. Thermal resistance (Rth) of PIC die structure 200 is further estimated to be reduced by at least 30% relative to an alternative architecture lacking metallization body 810.

As further illustrated in FIG. 8A, metallization body 810 may be coplanar with one or more other metallization features, such as one or more other metallization bodies positioned over other active optical devices (e.g., other HSL structures, SOA structures, etc.) and/or electrical interconnects 820. All such metallizations features may, for example, have substantially the same thickness, indicating they were fabricated concurrently. FIG. 8B illustrates an orthogonal cross-sectional view of PIC die structure 200 passing through a width W6 of HSL structure 500.

As depicted in FIG. 8A and FIG. 8B, metallization body 810 is not fully planarized, indicative of formation by a semi-additive plating process. Nevertheless, thickness T₁ is sufficiently large to significantly broaden topographic features of HSL structure 500. Metallization body 810 has a width W₇ in a second direction (e.g., along y-axis) coincident with width W₆. In exemplary embodiments, width W₇ is at least equal to width W₆, and advantageously greater than width W₆, expanding the width of a path of high thermal conductivity. In some embodiments where III-V mesa 524 has a width W₅ of less than 60 μm, metallization body 810 has a width W₇ of at least 80 μm. In exemplary embodiments where metallization body 810 is predominantly copper and has a thickness T₁ of at least 3 μm, width W₇ is at least 150 μm for an area of at least 150*L₁ μm². Although width W₇ may be arbitrarily larger than W₅, reductions in thermal resistance may level off, for example beyond about 200.

As further illustrated in the plan view of FIG. 8C, metallization body 810 has an area (footprint) that is much larger than a corresponding area (footprint) of HSL structure 500. This larger area of metallization body 810 encompasses, or fully covers, the underlying area of HSL structure 500, providing a top-side path of high thermal conductivity localized to HSL structure 500.

With PIC die structure 200 substantially complete, methods 100 (FIG. 1) end at output 140 where a PIC die is assembled into a photonic device package. Any known packaging may be assembled with a PIC structure that includes a body of metallization over an active optical device. In some exemplary embodiments, packaging includes a thermal interface material on a top side of a PIC structure. The thermal interface material is advantageously in direct contact with a body of metallization integrated into the PIC die. Packaging may further comprise a heat sink external over the PIC die, for example thermally coupled to the PIC die through thermal interface material.

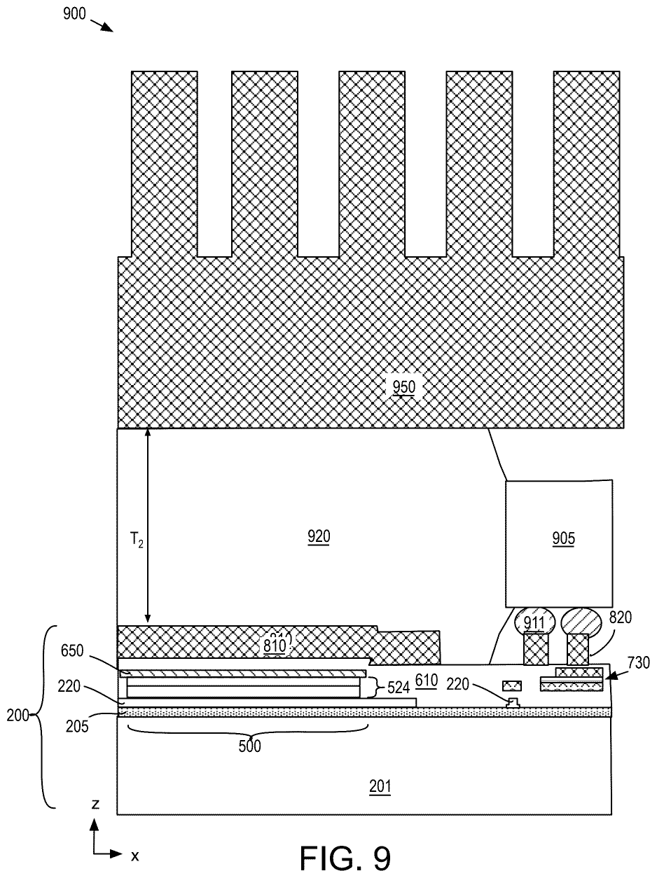

FIG. 9 is a cross-sectional view of a PIC package 900 comprising PIC die structure 200 and a thermal interface material (TIM) 920 in contact with metallization body 810. TIM 920 is to convey heat from metallization body 810 to an external heat sink 950. Although of a material that has favorable thermal conductivity, TIM 920 can be expected to have higher thermal resistance than metallization body 810. Metallization body 810 is therefore advantageously dimensioned to be functional as a PIC die-level heat spreader to spread the series thermal resistance of TIM 920 over a greater area and thereby better extract heat to a package-level thermal solution. Heat sink 950 may have any architecture known to dissipate heat. Heat sink 950 may also be any alternative thermal solution, such as a heat pipe, etc.

TIM 920 may be any compressible intermediary that can improve thermal conductivity between metallization body 810 and heat sink 950 that would otherwise be difficult to place in close thermal contact. TIM 920 may be a viscous fluid, often referred to as a “thermal grease” or “thermal jelly.” Although a thermal grease can offer good thermal conductivity, TIM 920 may instead be a solid pad comprising a material that is in a more stable solid/condensed phase, but still displays good thermal conductivity and is compressible (e.g., <55 on the Shore A hardness scale). TIM 920 may have any thickness T₂, but in some embodiments TIM thickness T₂ may be 250-500 μm.

TIM 920 may be a homogenous body, a multilayered laminate, or a composite. TIM 920 may be, for example, a polymer or polymer composite (e.g., metallic or ceramic particles in silicone), metal, phase change material (PCM), graphite sheet, carbon nanotube composite, low-melting temperature metal, or metal alloy (e.g., solder). While many polymers may be suitable, some examples include silicone-based polymers (i.e., polysiloxanes comprising silicon, oxygen, carbon), synthetic rubbers, and natural rubber. Exemplary carbon-based TIMs comprise a filler of graphitic material (e.g., crystalline graphite, pyrolytic graphite) suspended in a binder or matrix resin having a low bulk modulus, displaying high compressibility (e.g., 40%, or more).

For embodiments where PIC die structure 200 includes one or more electrical interconnects 820, those interconnects may be coupled to an electrical IC (EIC) die 905, for example through a solder feature 911. EIC die 905 may include electrical devices (e.g., transistors) fabricated upon a substrate (e.g., silicon), which are interconnected into circuitry by IC die interconnect metallization. In the illustrated example EIC die 905 is flip-chip assembled upon PIC die structure 200. However, in alternative embodiments PIC die structure 200 may be flip-chip assembled upon a host component (not depicted), such as an EIC die or package substrate. For such embodiments, TIM 920 may be replaced with an underfill material in direct contact with metallization body 810 and that is then part of the thermal path to the host component.

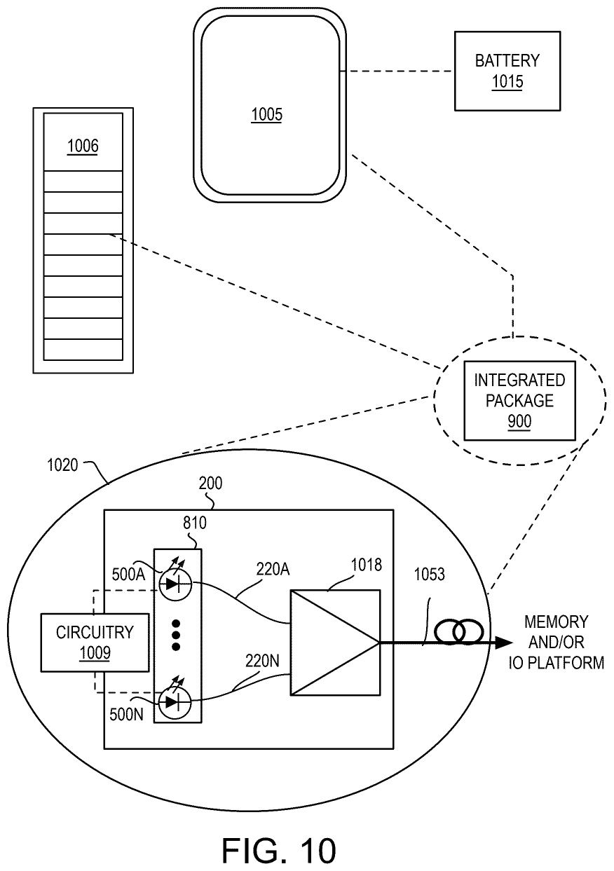

Active optical devices and the integrated heat sinks described herein may be implemented in a wide variety of applications, systems, and platforms. FIG. 10 illustrates a mobile computing platform 1005 and data server platform 1006, each employing an optical link with one or more active hybrid silicon optical device structures comprising a high index spacer, for example as described elsewhere herein. Platform 1006 may be any commercial server including any number of high-performance computing systems disposed within a rack and networked together for electronic data processing. Mobile platform 1005 may be any portable device configured for each of electronic data display, electronic data processing, wireless electronic data transmission, or the like. For example, the platform 1005 may be any of a tablet, a smart phone, laptop computer, etc., and may include an integrated or disintegrated package 900, and a battery power supply 1015.

Platforms 1005 or 1006 may each include PIC package 900, illustrated in expanded view 1020. PIC package 900 includes PIC die structure 200 further comprising a silicon waveguide-coupled HSL structure integrated with metallization body 810 operable as a die-level heat spreader, for example as described elsewhere herein. As shown, PIC die structure 200 is an optical transmitter over a plurality of optical wavelengths, each wavelength output by one of a plurality of HSL structures 500A-500N through a plurality of optical waveguides 220A-220N. HSL structures 500A-500N may output at different center wavelengths (e.g., with 0.5-3.0 nm spacing). Waveguides 220A-220N coupled with an optical multiplexer 1018 into wave division multiplexed (e.g., DWDM) optical beam. The optical beam may be coupled off-chip to an optical wire or fiber 1053, for example through a top-side coupler or edge coupler. HSL structures 500A-500N are electrically coupled to integrated comb driver circuitry 1009, which may for example further include a voltage supply. In certain embodiments, comb driver circuitry 1009 is implemented with CMOS transistors external of PIC 200.

As further shown in FIG. 10, one or more metallization bodies 810 may be co-located over HSL structures 500A-500N. In some examples, a separate metallization body 810 is over each individual one of HSL structures 500A-500N. In other examples, a single metallization body 810 spans more than one (e.g., all) of HSL structures 500A-500N. For either example, a single TIM and package-level thermal solution may be coupled to the one or more metallization bodies 810.

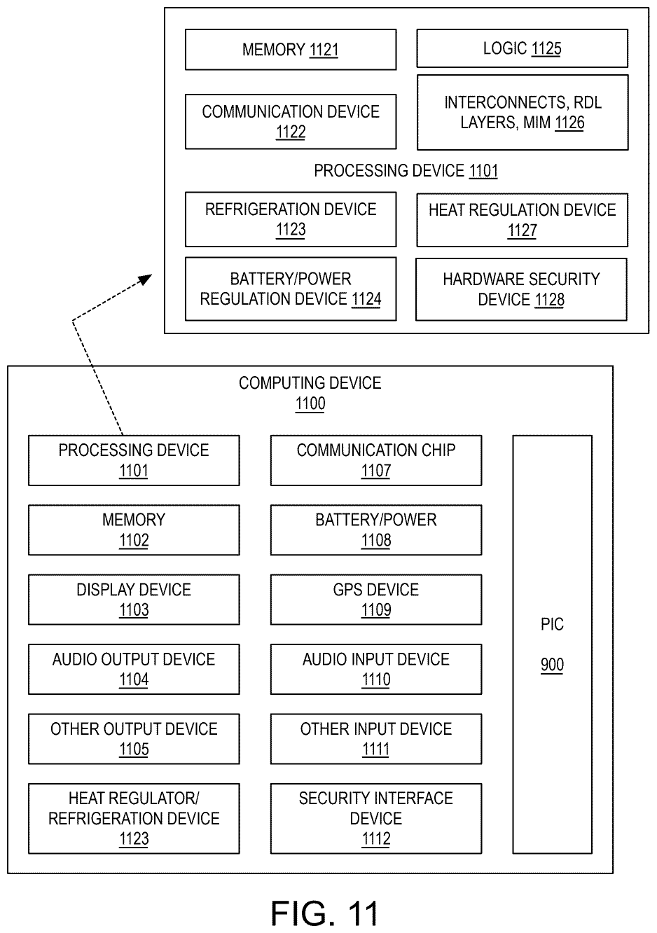

FIG. 11 is a block diagram of a cooled computing device 1100 in accordance with some embodiments. For example, one or more components of computing device 1100 may include PIC die structure 200 further including any of the active hybrid silicon optical device structures and PIC-level integrated heat spreaders discussed elsewhere herein.

A number of components are illustrated in FIG. 11 as included in computing device 1100, but any one or more of these components may be omitted or duplicated, as suitable for the application. In some embodiments, some of the components included in computing device 1100 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Additionally, in various embodiments, computing device 1100 may not include one or more of the components illustrated in FIG. 11, but computing device 1100 may include interface circuitry for coupling to the one or more components. For example, computing device 1100 may not include memory 1102, but may include memory interface circuitry (e.g., a connector and driver circuitry) to which memory 1102 may be coupled.

Computing device 1100 may include a processing device 1101 (e.g., one or more processing devices). As used herein, the term processing device or processor indicates a device that processes electronic data from registers and/or memory to transform that electronic data into other electronic data that may be stored in registers and/or memory. Processing device 1101 may include a memory 1121, a communication device 1122, a refrigeration/active cooling device 1123, a battery/power regulation device 1124, logic 1125, interconnects 1126, a heat regulation device 1127, and a hardware security device 1128.

Processing device 1101 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1101 may include a memory 1121, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 1101 shares a package with memory 1121. This memory may be used as cache memory and may include embedded dynamic random-access memory (eDRAM) or spin transfer torque magnetic random-access memory (STT-M RAM).

Computing device 1100 may include a heat regulation/refrigeration device 1123. Heat regulation/refrigeration device 1123 may maintain processing device 1101 (and/or other components of computing device 1100) at a predetermined low temperature during operation. This predetermined low temperature may be any temperature discussed elsewhere herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an optical data link comprising PIC die structure 200 to transmit and/or receive optical communications through an optical multiplexed fiber.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a global positioning system (GPS) device 1109 (or corresponding interface circuitry, as discussed above). GPS device 1109 may be in communication with a satellite-based system and may receive a location of computing device 1100, as known in the art.

Computing device 1100 may include another output device 1105 (or corresponding interface circuitry, as discussed above). Examples include an audio codec, a video codec, a printer, a wired or wireless transmitter for providing information to other devices, or an additional storage device.

Computing device 1100 may include another input device 1111 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, managing access lists, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that practice of the disclosed techniques and architectures is not limited to the embodiments so described but can be modified and altered without departing from the scope of the appended claims. For example, the above embodiments may include specific combinations of features as further provided below.

In first examples, an apparatus comprises an optical waveguide comprising silicon, an optical device comprising III-V material over a length of the optical waveguide, contact metallization coupled to the optical device, and a body of metallization over the optical device and over the contact metallization.

In second examples, for any of the first examples the III-V material comprises a III-V optical gain material between a p-type III-V layer and an n-type III-V layer. The contact metallization comprises a first contact metallization in contact with the p-type III-V layer, and a second contact metallization in contact with the n-type III-V layer. The active device occupies a first area of a photonic integrated circuit (PIC), and the body of metallization occupies a second area of the PIC, the second area exceeding, and completely encompassing the first area.

In third examples, for any of the second examples the III-V optical gain material is within a mesa having a first transverse width less than 60 μm along a first dimension of a photonic integrated circuit (PIC). The body of metallization has a second transverse width of at least 80 μm.

In fourth examples, for any of the third examples the second transverse width is at least 150 μm.

In fifth examples, for any of the first through fourth examples the body of metallization has a layer thickness of at least 3 μm.

In sixth examples, for any of the fifth examples the body of metallization has a layer thickness exceeding 5 μm.

In seventh examples, for any of the first through sixth examples the body of metallization is predominantly copper, gold or silver.

In eighth examples, for any of the third through seventh examples the mesa has a first longitudinal length and wherein the body of metallization has a second longitudinal length exceeding the first longitudinal length.

In ninth examples, for any of the first through eighth examples the optical waveguide is crystalline silicon, has a width less than 1 μm, and is over a substrate comprising a buried insulator layer further comprising silicon and oxygen.

In tenth examples, for any of the first through ninth examples, the apparatus comprises a thermal interface material (TIM) in contact with the body of metallization.

In eleventh examples, for any of the tenth examples the apparatus comprises a heat sink in contact with the TIM.

In twelfth examples, an optical transmitter comprises a photonic integrated circuit (PIC), comprising a silicon optical waveguide extending over a crystalline silicon substrate, a hybrid silicon III-V laser (HSL) optically coupled to the silicon optical waveguide, and a body of metallization over the HSL. The optical transmitter comprises a heat sink, and a thermal interface material (TIM) between the heat sink and the PIC. The body of metallization is between the TIM and the HSL.

In thirteenth examples, for any of the twelfth examples the TIM has a thickness of at least 250 μm, and the body of metallization has a thickness of at least 3 μm.

In fourteenth examples, for any of the twelfth through thirteenth examples the TIM comprises a pad preform or a paste, the body of metallization is predominantly copper and the TIM is in contact with the body of metallization.

In fifteenth examples, for any of the twelfth through fourteenth examples the PIC has a first area, the HSL occupies a second area within the first area of the PIC, the body of metallization occupies a third area of the PIC, smaller than the first area, but larger than the second area and overlapping an entirety of the second area.

In sixteenth examples, for any of the twelfth through fifteenth examples the HSL is a first HSL of a plurality of HSLs optically coupled to a plurality of silicon optical waveguides, NS the body of metallization overlaps the plurality of HSLs.

In seventeenth examples a method comprises receiving a photonic integrated circuit (PIC) die, the PIC die comprising a hybrid silicon III-V optical device and a body of metallization over the hybrid silicon III-V optical device. The method comprises applying a thermal interface material (TIM) to the PIC or to a heat sink, and assembling the heat sink with the PIC, the assembling placing the TIM in contact with the body of the metallization.

In eighteenth examples, for any of the seventeenth examples the method comprises forming the hybrid silicon III-V optical device from a III-V material stack and an optical waveguide within the silicon substrate, forming contact metallization to the hybrid silicon III-V optical device, and forming the body of metallization over, and electrically isolated from, the contact metallization.

In nineteenth examples, for any of the eighteenth examples the body of metallization has a thickness exceeding 3 μm over an area exceeding that of the hybrid silicon III-V optical device.

In twentieth examples, for any of the nineteenth examples, the hybrid silicon III-V optical device is a laser or semiconductor optical amplifier, the body of metallization is predominantly copper, the body of metallization has a transverse width of at least 80 μm, and the body of metallization has a longitudinal length exceeding that of the hybrid silicon III-V optical device.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosed techniques and architectures should therefore be determined with reference to the appended claims, along with the full scope of equivalents to which such claims are entitled.

What is claimed is:

1. An apparatus, comprising:
an optical waveguide comprising silicon;
an optical device comprising III-V material over a length of the optical waveguide;
contact metallization coupled to the optical device; and
a body of metallization over the optical device and over the contact metallization.

2. The apparatus of claim 1, wherein:
the III-V material comprises a III-V optical gain material between a p-type III-V layer and an n-type III-V layer;
the contact metallization comprises a first contact metallization in contact with the p-type III-V layer, and a second contact metallization in contact with the n-type III-V layer, and
the optical device occupies a first area of a photonic integrated circuit (PIC); and
the body of metallization occupies a second area of the PIC, the second area exceeding, and encompassing the first area.

3. The apparatus of claim 2, wherein the III-V optical gain material is within a mesa having a first transverse width less than 60 μm along a first dimension of a photonic integrated circuit (PIC), and wherein the body of metallization has a second transverse width of at least 80 μm.

4. The apparatus of claim 3, wherein the second transverse width is at least 150 μm.

5. The apparatus of claim 3, wherein the mesa has a first longitudinal length and wherein the body of metallization has a second longitudinal length exceeding the first longitudinal length.

6. The apparatus of claim 2, wherein the body of metallization has a layer thickness of at least 3 μm.

7. The apparatus of claim 6, wherein the body of metallization has a layer thickness exceeding 5 μm.

8. The apparatus of claim 6, wherein the body of metallization is predominantly copper, gold or silver.

9. The apparatus of claim 1, wherein the optical waveguide is crystalline silicon, has a width less than 1 μm, and is over a substrate comprising a buried insulator layer further comprising silicon and oxygen.

10. The apparatus of claim 1, further comprising a thermal interface material (TIM) in contact with the body of metallization.

11. The apparatus of claim 10, further comprising a heat sink in contact with the TIM.

12. An optical transmitter, comprising:
a photonic integrated circuit (PIC), comprising:
a silicon optical waveguide extending over a crystalline silicon substrate;
a hybrid silicon III-V laser (HSL) optically coupled to the silicon optical waveguide; and
a body of metallization over the HSL;
a heat sink; and
a thermal interface material (TIM) between the heat sink and the PIC, wherein the body of metallization is between the TIM and the HSL.

13. The optical transmitter of claim 12, wherein:
the TIM has a thickness of at least 250 μm; and
the body of metallization has a thickness of at least 3 μm.

14. The optical transmitter of claim 13, wherein:
the TIM comprises a pad preform or a paste;
the body of metallization is predominantly copper; and
the TIM is in contact with the body of metallization.

15. The optical transmitter of claim 12, wherein:
the PIC has a first area;
the HSL occupies a second area within the first area of the PIC; and
the body of metallization occupies a third area of the PIC, smaller than the first area, but larger than the second area and overlapping an entirety of the second area.

16. The optical transmitter of claim 12, wherein:
the HSL is a first HSL of a plurality of HSLs optically coupled to a plurality of silicon optical waveguides; and
the body of metallization overlaps the plurality of HSLs.

17. A method comprising:
receiving a photonic integrated circuit (PIC) die, wherein the PIC die comprises a hybrid silicon III-V optical device and a body of metallization over the hybrid silicon III-V optical device;
applying a thermal interface material (TIM) to the PIC or to a heat sink; and
assembling the heat sink with the PIC, the assembling placing the TIM in contact with the body of the metallization.

18. The method of claim 17, further comprising:
forming the hybrid silicon III-V optical device from a III-V material stack and an optical waveguide within a silicon substrate;
forming contact metallization to the hybrid silicon III-V optical device; and
forming the body of metallization over, and electrically isolated from, the contact metallization.

19. The method of claim 18, wherein the body of metallization has a thickness exceeding 3 μm over an area exceeding that of the hybrid silicon III-V optical device.

20. The method of claim 19, wherein:
the hybrid silicon III-V optical device is a laser or semiconductor optical amplifier;
the body of metallization is predominantly copper;
the body of metallization has a transverse width of at least 80 μm; and
the body of metallization has a longitudinal length exceeding that of the hybrid silicon III-V optical device.
